(19) United States
(12) Patent Application Publication
(10) Pub. No.: US 2002/0160603 A1
(43) Pub. Date: Oct. 31, 2002

(54) Method for forming salicide protected circuit with organic material

(75) Inventor: Shin-Yi Tsai, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/843,750

(22) Filed: Apr. 30, 2001

(51) Int. Cl. H01L 21/44; H01L 21/4763

(52) U.S. Cl. 438/682; 438/663; 438/655; 438/649; 438/651

(57) ABSTRACT

First of all, a semiconductor substrate that has a memory array and a periphery region thereon is provided. Then a barrier layer is formed on the gate devices of the memory array and the periphery region and on the semiconductor substrate. Next, an organic layer is formed on the barrier layer. Afterward, removing the organic layer and the barrier layer until exposing the gate devices of the memory array and the periphery region. The remainder of the organic layer is then removed by way of using an ashing process. Subsequently, a photoresist layer is formed on the memory array, and the barrier layer of the periphery region is etched until exposing the surface of the semiconductor substrate. Finally, performing a silicide process after removing the photoresist layer, so as to individually form a salicide layer on the gate devices of the memory array and the periphery region, and on the semiconductor substrate of the periphery region.

### BACKGROUND OF THE INVENTION

1. Field of the Invention

The present invention relates generally to a method for forming a salicide, and more particularly to a process for forming a salicide protected circuit.

2. Description of the Prior Art

As semiconductor devices, such as Metal-Oxide-Semiconductor devices, become highly integrated the area occupied by the device shrinks, as well as the design rule. With advances in the semiconductor technology, the dimensions of the integrated circuit (IC) devices have shrunk to the deep sub-micron range. When the semiconductor device continuously shrinks to the deep sub-micron region, some problems described below are incurred due to the process of scaling down.

Cross-sectional views of a process for forming a salicide protected circuit of the known prior art are illustrated in FIG. 1A to FIG. 1D. First of all, a semiconductor substrate 100 is provided, and a memory array 110 having gate devices 115 and a periphery region 120 having gate devices 125 are formed on the semiconductor substrate 100. Then, a barrier layer 130 is formed on the gate devices 115, 125, and the semiconductor substrate 100. Next, performing an etching process to etch the barrier layer 130 until exposing the surface of the gate devices 115 and 125, wherein an opening 140 must be formed between the gate devices 125 of the periphery region 120. Afterward, the salicide layer 150 is formed on the gate devices 115, 125 and the opening 140 by way of using a silicide process.

The evolution of integrated circuits has evolved such that scaling down the device geometry. In the deep sub-micron technology of semiconductors, it's necessary that the salicide layer be formed on the gate and junction to decrease resistance. Because the design rule includes the memory array and the periphery region, the salicide layer 150 has to be formed on the gate device 115 of the memory array 110 to decrease the resistance of the word line, and the salicide layer 150 also has to be formed on the gate device 125 of the periphery region 120 and the channels between the gate device 125.

Furthermore, if the salicide layer 150 is formed on the channels between the gate device 115 of the memory array 110, the Buried Diffusion-to- Buried Diffusion effect (BD-to-BD) will result in reduced performance of the device. Therefore, for preventing the Buried Diffusion-to- Buried Diffusion effect (BD-to-BD), it is necessary that the barrier layer 130 is formed over the channels between the gate device 115 of the memory array 110 to avoid the junction leakage. The conventional process is very difficult to perform in below deep sub-micron. Especially, when the channel length between the gate devices 115 of the memory array 110 is scaled down, the method for forming the barrier layer 130 becomes more difficult.

Moreover, when the barrier layer 130 is etched in the conventional process, the opening 140 of the channel between the gate devices 115 of the memory array 110. Therefore, the thickness of the barrier layer 130 in the memory array 110 has to be increased, and the thickness of the barrier layer 130 in the periphery region 120 has to be decreased. Nevertheless, the process above is very complex and hard to control. On the other hand, for the inorganic material, increasing the thickness of the barrier layer 130 is very hard, and it is more difficult to remove the barrier layer 130, so that it can not be reworked in return will increase the process cost.

In accordance with the above description, a new and improved method for forming the salicide is therefore necessary, so as to raise the yield and quality of the follow-up process.

### SUMMARY OF THE INVENTION

In accordance with the present invention, a method is provided for fabricating the salicide protected circuit that substantially overcomes the drawbacks of the above mentioned problems that arise from conventional methods.

Accordingly, it is a main object of the present invention to provide a method for fabricating the salicide. This invention can form the salicide layer on the gate devices of the memory array and the periphery region and channel of the periphery region with an organic material, so as to avoid forming the salicide layer on the channel between the gate device of the memory array. Hence, the present invention is appropriate for deep sub-micron technology in providing semiconductor devices.

Another object of the present invention is to provide a process for forming the salicide protected circuit. The present invention can prevent the salicide layer from being formed on the channel of the memory array by way of using an organic material, so as to avoid forming results in the Buried Diffusion-to-Buried Diffusion effect (BD-to-BD). Furthermore, this invention also holds the spacer width between the gate devices, so that the characteristic of the devices does not shift. For the organic material, there are many advantages; easy to fabricate and remove so that it can be reworked. Therefore, this invention can reduce the complexity of the conventional process and hence cost reduction. Thus, the present invention can correspond to economic effect.

In accordance with the present invention, a new method for forming the semiconductor devices is disclosed. First of all, a semiconductor substrate that has a memory array and a periphery region thereon is provided. Then a barrier layer is formed on the gate devices of the memory array and the periphery region and on the semiconductor substrate. Next, an organic layer is formed on the barrier layer, wherein forming the organic layer can avoid forming the salicide layer on the channel between the gate device of the memory array, and that prevent the Buried Diffusion-to-Buried Diffusion effect (BD-to-BD ). Afterward, removing the organic layer and the barrier layer until the gate devices of the memory array and the periphery region is exposed. The remainder of the organic layer is then removed by way of using an ashing process. Subsequently, a photoresist layer is formed on the memory array, and the barrier layer of the periphery region is etched until exposing the surface of the semiconductor substrate. Finally, performing a silicide process after removing the photoresist layer, so as to individually form a salicide layer on the gate devices of the memory array and the periphery region, and on the semiconductor substrate of the periphery region. Especially, on the semiconductor substrate of the memory array, the salicide layer can not be formed to prevent the Buried Diffusion-to- Buried Diffusion effect (BD-to-BD) from being produced.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1D show cross-sectional views illustrative of the salicide protected circuit with the conventional process; and

FIG. 2A to FIG. 2F show cross-sectional views illustrative of various stages for forming a salicide protected circuit with an organic layer in accordance with the embodiment of the present invention.

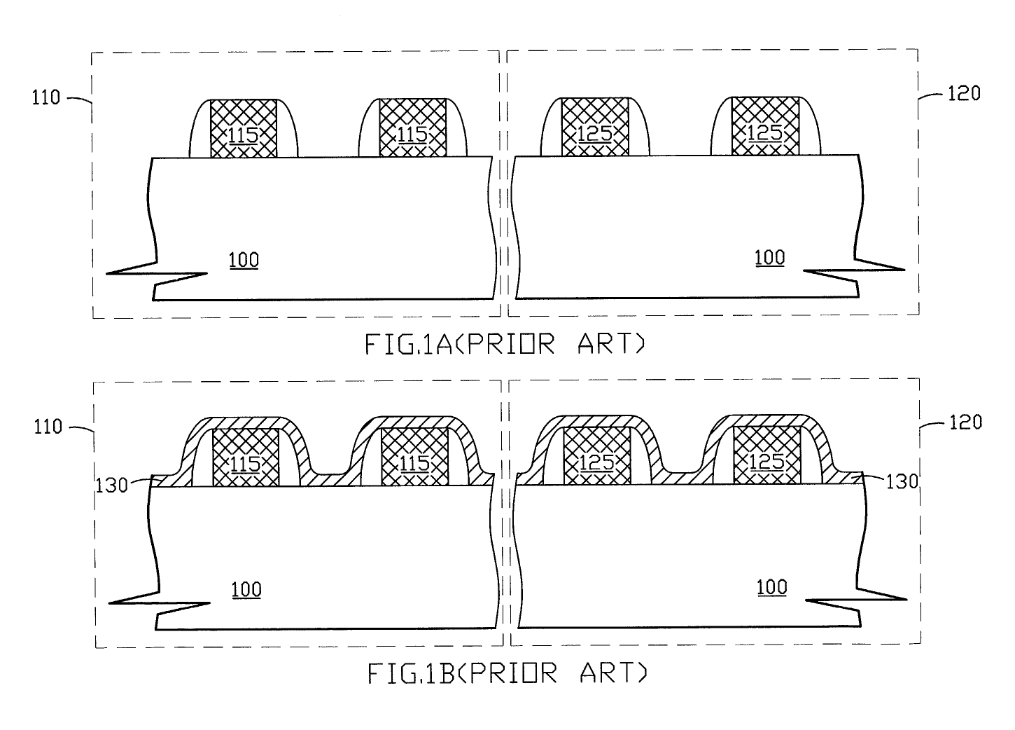

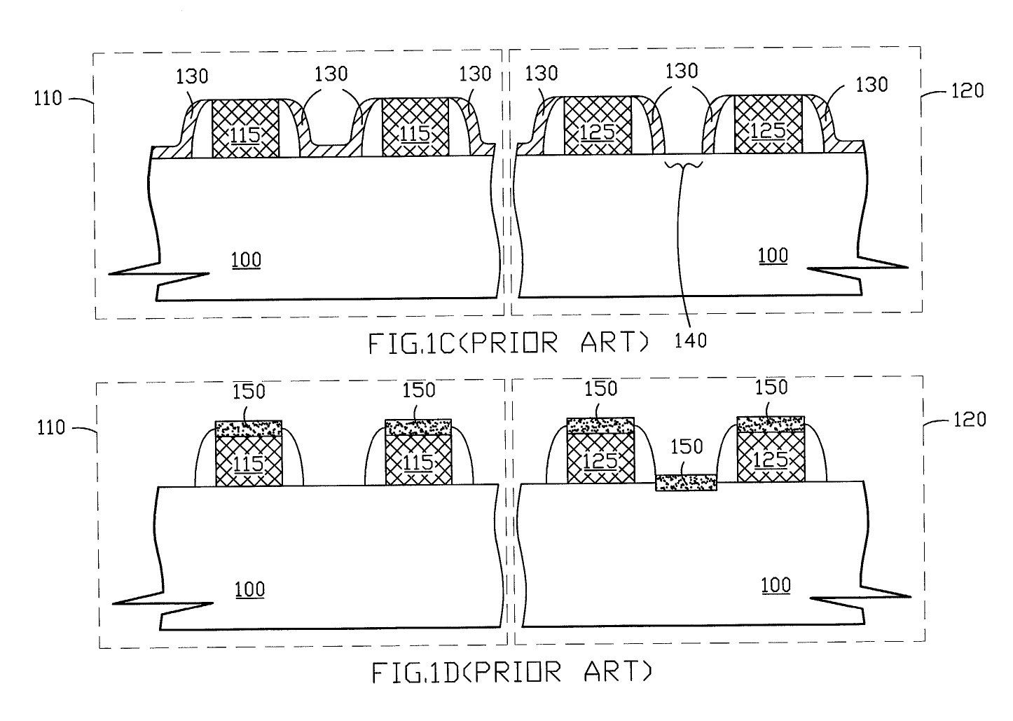

### DESCRIPTION OF THE PREFERRED EMBODIMENT

A preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

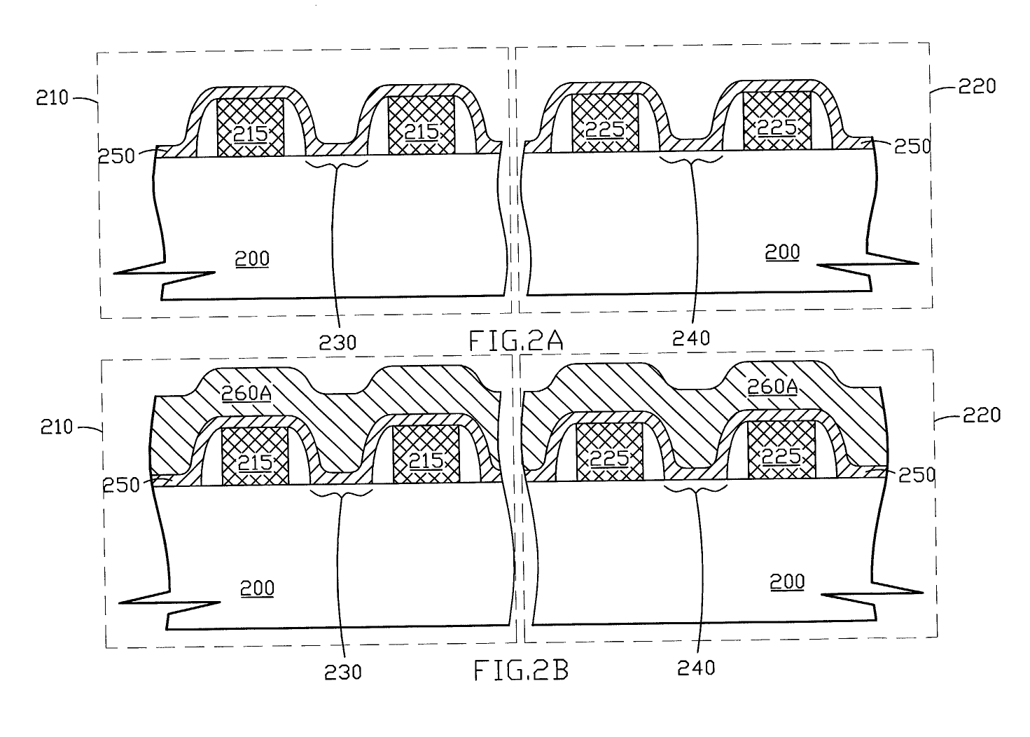

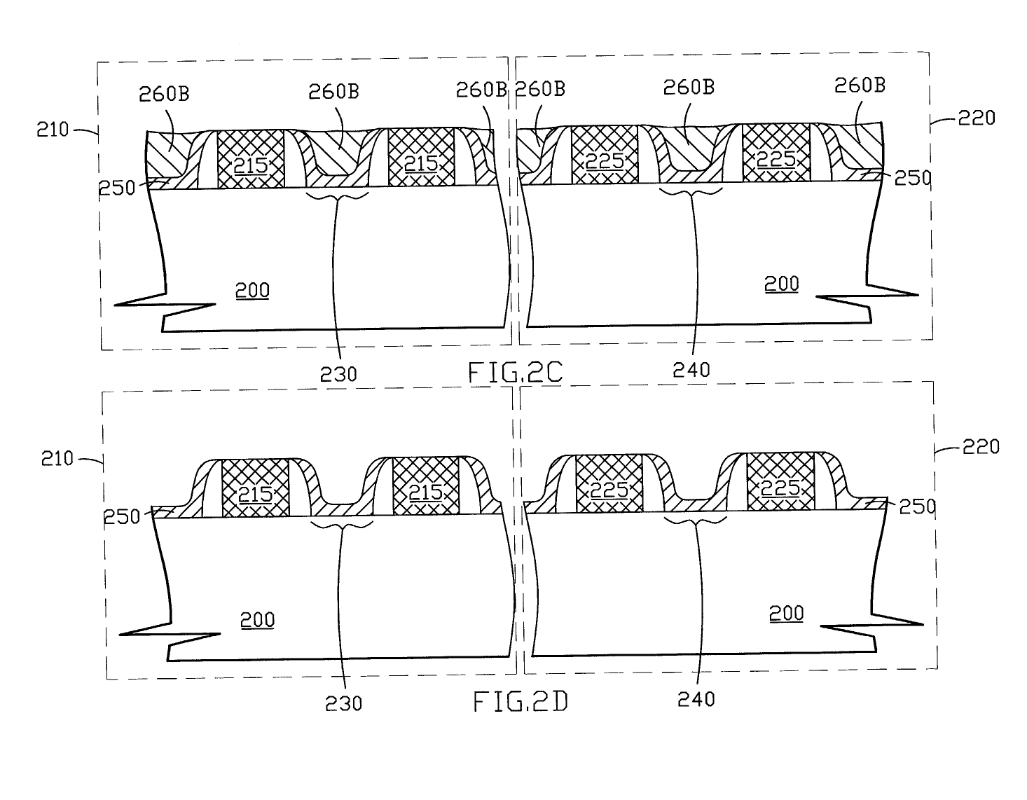

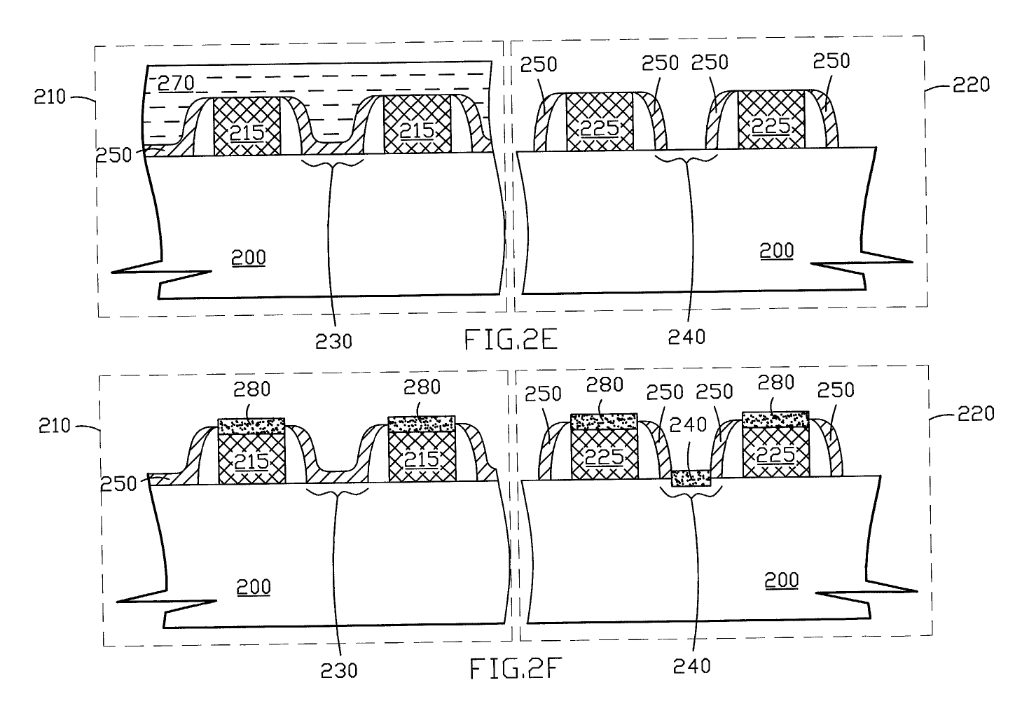

As illustrated in FIG. 2A, in one embodiment of the present invention, a semiconductor substrate 200, that has a memory array 210 and a periphery region 220 thereon, is provided, wherein the periphery region 220 comprises a plurality of gate devices 225 on the semiconductor substrate 200 that are spaced apart by a predetermined distance 240 as the channels, and the memory array 210 comprises a plurality of gate devices 215 on the semiconductor substrate 200 that are spaced apart from one another by a predetermined distance 230 as the channels. Then a barrier layer 250 is formed on the plurality of gate devices 215, 225 of the memory array 210 and the periphery region 220 and on the semiconductor substrate 200 that are located on the predetermined distance 230, 240, wherein the barrier layer 250 comprises a dielectric layer.

Referring to FIG. 2B, in this embodiment, an organic layer 260A is formed on the barrier layer 250, wherein the method for forming the organic layer 260A comprises a deposition process or a coating process, and the material of the organic layer 260A comprises a hydrocarbon compound. After removing the organic layer 260A and the barrier layer 250 until exposing the gate devices 215, 225 of the memory array 210 and the periphery region 220, and that the position on the predetermined distance 230, 240 remains the remainder of the organic layer 260B, wherein the method for removing the organic layer 260A and the barrier layer 250 comprises an etching back process or a chemical-mechanical-polishing process (CMP), as shown in FIG. 2C.

Referring to FIG. 2D, in this embodiment, the remainder of the organic layer 260B is stripped, wherein the method for stripping the remainder of the organic layer 260B comprises an ashing process. Subsequently, a photoresist layer 270 is formed on the memory array 210, and then the barrier layer 250 of the periphery region 220 is etched by way of using the photoresist layer 270 and the plurality of gate devices 225 of the periphery region 220 as the photoresist masks until exposing the surface of the semiconductor substrate 200 that are located on the predetermined distance 240, wherein the method for etching the barrier layer 250 of the periphery region 220 comprises a dry etching process, as shown in FIG. 2E.

Referring to FIG. 2F, in this embodiment, after the photoresist layer 270 is removed, a salicide layer 280 is formed on the gate device 215, 225 of the memory array 210 and the periphery region 220, also upon the semiconductor substrate 200 that's located on the predetermined distance 240 of the periphery region 220 by way of using a silicide process. Particularly on the semiconductor substrate 200 that's located on the predetermined distance 230 of the memory array 210, the salicide layer 280 can not be formed to prevent the Buried Diffusion-to- Buried Diffusion effect (BD-to-BD) from being produced.

In this embodiment of the present invention, as discussed above, this invention can form the salicide layer on the gate devices of the memory array and the periphery region and the channel of the periphery region with the organic material, so as to avoid forming the salicide layer on the channel between the gate devices of the memory array. Hence, the present invention is appropriate for deep sub-micron technology to provide semiconductor devices. Furthermore, the present invention can prevent a salicide layer from being formed on the channel of the memory array by way of using the organic material, so as to avoid the Buried Diffusion-to- Buried Diffusion effect (BD-to-BD, this invention also holds the spacer width in the periphery region, so that the characteristic of the devices is not shifted. On the other hand, for the organic material, there are many advantages such as it's easy to fabricate and to remove, and then reworked. Therefore, this invention can reduce the complexity of conventional process and, hence, cost. Thus, the present invention can correspond to economic effect.

Of course, it is possible to apply the present invention to the salicide protected circuit process, and also it is possible to the present invention to any one salicide process in the semiconductor devices. Also, this invention can be applied to form the organic layer concerning the salicide protected circuit process used for performing silicide process has not been developed at present. Method of the present invention is the best salicide protected circuit compatible process for deep sub-micro process.

Obviously, many modifications and variations of the present invention are possible in light of the above teachings. It is therefore to be understood that within the scope of the appended claims, the present invention may be practiced other than as specifically described herein.

Although the specific embodiment has been illustrated and described, it will be obvious to those skilled in the art that various modifications may be made without departing from what is intended to be limited solely by the appended claims.

What is claimed is:

1. A method for forming a salicide layer, the method comprising:
providing a semiconductor substrate;
forming a plurality of first gate devices and a plurality of second gate devices on said semiconductor substrate, wherein said plurality of first gate devices and said plurality of second gate devices are spaced apart from one another by a predetermined distance;
forming a barrier layer on said plurality of first gate devices and said plurality of second gate devices, and on said semiconductor substrate that are located on said predetermined distance;
forming a organic layer on said barrier layer;
removing said organic layer and said barrier layer until exposing said plurality of first gate devices and said plurality of second gate devices, wherein the position on said predetermined distance remain the remainder of said organic layer;
stripping the remainder of said organic layer;
forming a photoresist layer on said plurality of first gate devices;
performing an etching process by way of using said photoresist layer and said plurality of second gate devices as the etching masks to etch said barrier layer until exposing the surface of said semiconductor substrate that are located on said predetermined distance between said plurality of second gate devices;
removing said photoresist layer; and
performing a silicide process to individually form said salicide layer on said plurality of first gate devices and said plurality of second gate devices, and on said semiconductor substrate that are located on said predetermined distance between said plurality of second gate devices.

2. The method according to claim 1, wherein said semiconductor substrate comprises a memory array.

3. The method according to claim 2, wherein said memory array comprises said plurality of first gate devices.

4. The method according to claim 1, wherein said semiconductor substrate comprises a periphery region.

5. The method according to claim 1, wherein said periphery region comprises said plurality of second gate devices.

6. The method according to claim 1, wherein the method for forming said organic layer comprises a depositing process.

7. The method according to claim 1, wherein the method for forming said organic layer comprises a coating process.

8. The method according to claim 1, wherein the material of said organic layer comprises a hydrocarbon compound.

9. The method according to claim 1, wherein the method for removing said organic layer and said barrier layer comprises an etching back process.

10. The method according to claim 1, wherein the method for removing said organic layer and said barrier layer comprises a chemical-mechanical-polishing process.

11. The method according to claim 1, wherein the method for stripping the remainder of said organic layer comprises an ashing process.

12. The method according to claim 1, wherein said etching process comprises a dry etching process.

13. A method for forming a salicide protected circuit, the method comprising:
providing a semiconductor substrate that has a memory array and a periphery region thereon;
forming a dielectric layer on the devices of said memory array and said periphery region and on said semiconductor substrate;
performing a coating process with an organic material to form an organic layer on said dielectric layer;
performing an etching back process to remove a portion of said organic layer and said dielectric layer until exposing the devices surface of said memory array and said periphery region;
stripping the remainder of said organic layer by way of using an ashing process;
forming a photoresist layer on the devices of said memory array;
performing an etching process by way of using said photoresist layer and the devices of said periphery region as the etching masks to etch said dielectric layer in said periphery region until exposing the surface of said semiconductor substrate in said periphery region;
removing said photoresist layer; and
performing a silicide process to individually form a salicide layer on the devices of said memory array and said periphery region and on said semiconductor substrate of said periphery region, so as to form said salicide protected circuit.

14. The method according to claim 13, wherein the method for forming said organic layer comprises a depositing process.

15. The method according to claim 13, wherein said organic material comprises a hydrocarbon compound.

16. The method according to claim 13, wherein the method for removing said organic layer and said dielectric layer comprises a chemical-mechanical-polishing process.

17. The method according to claim 13, wherein said etching process comprises a dry etching process.

18. A method for forming a salicide protected circuit, the method comprising:
providing a semiconductor substrate;
forming a memory array and a periphery region on said semiconductor substrate, wherein said memory array has a plurality of first gates that are spaced apart from one another by a first predetermined distance, and said periphery region has a plurality of second gates that are spaced apart from one another by a second predetermined distance;
forming a barrier layer on said plurality of first gates and said plurality of second gates, and on said semiconductor substrate that are located on said first predetermined distance and said second predetermined distance;
performing a depositing process with an organic material to form an organic layer on said barrier layer;
performing a chemical-mechanical-polishing process to remove said organic layer and said barrier layer until exposing said plurality of first gates and said plurality of second gates, wherein the position on said first predetermined distance and said second predetermined distance remain the remainder of said organic layer;
stripping the remainder of said organic layer by way of using an ashing process;
forming a photoresist layer on said plurality of first gates and said first predetermined distance of said memory array;
performing an etching process by way of using said photoresist layer and said plurality of second gates as the etching masks to etch said barrier layer in said periphery region until exposing the surface of said semiconductor substrate that are located on said second predetermined distance between said plurality of second gates;
removing said photoresist layer; and
performing a silicide process to individually form a salicide layer on said plurality of first gates and said plurality of second gates, and on said semiconductor substrate that are located on said second predetermined distance between said plurality of second gates, so as to form said salicide protected circuit.

19. The method according to claim 18, wherein the method for forming said organic layer comprises a coating process.

20. The method according to claim 18, wherein the method for removing said organic layer and said barrier layer comprises an etching back process.
